(19) United States
(12) Patent Application Publication
(10) Pub. No.: US 2026/0242300 A1
(43) Pub. Date: Aug. 20, 2026

(54) METAL CARBIDE-COATED CARBON MATERIAL

(71) Applicant: SHIN-ETSU CHEMICAL CO., LTD., Tokyo (JP)

(72) Inventors: Akihiro HIRATE, Takasaki-shi (JP); Naoya MIYAJIMA, Annaka-shi (JP); Waichi YAMAMURA, Annaka-shi (JP)

(73) Assignee: SHIN-ETSU CHEMICAL CO., LTD., Tokyo (JP)

(21) Appl. No.: 19/160,731

(22) PCT Filed: Mar. 5, 2024
(86) PCT No.: PCT/JP2024/008309

§ 371 Date: Aug. 28, 2025

(30) Foreign Application Priority Data
Mar. 30, 2023 (JP) 2023-055681

(51) Int. Cl. C04B 41/50; C04B 35/52; C04B 41/45; C04B 41/87

(52) U.S. Cl. CPC C04B 41/5057; C04B 35/522; C04B 41/4531; C04B 41/87

(57) ABSTRACT

The present invention relates to a metal carbide-coated carbon material including a carbon substrate containing carbon as a main component and a metal carbide coating film covering at least part of the carbon substrate, in which the metal carbide constituting the metal carbide coating film is at least one metal carbide selected from the group consisting of tantalum carbide, niobium carbide, zirconium carbide, hafnium carbide, and tungsten carbide, and in which the metal carbide coating film has a chlorine concentration of 25,000 ppm·μm or less. The present invention can provide a metal carbide-coated carbon material that can prevent crystal polymorphism during crystal growth and epitaxial growth of semiconductor single crystals and improve the yield of semiconductor single crystals.

### TECHNICAL FIELD

The present invention relates to a metal carbide-coated carbon material in which the surface of a carbon substrate is covered with a metal carbide coating film.

### BACKGROUND ART

Tantalum carbide, niobium carbide, zirconium carbide, hafnium carbide, tungsten carbide, and other carbides have high melting points and excellent chemical stability, strength, toughness, and corrosion resistance. For this reason, carbide coating of carbon substrates can improve the properties of the carbon substrates, such as heat resistance, chemical stability, strength, toughness, and corrosion resistance. Carbide-coated carbon materials, in which the surface of a carbon substrate is coated with a carbide film, in particular tantalum carbide-coated carbon materials, are used as the components of an apparatus for producing single crystals of semiconductors such as silicon (Si), silicon carbide (SIC), and gallium nitride (GaN).

A widely known method for producing SiC bulk single crystals is the sublimation-recrystallization method (the modified Lely method). In the sublimation-recrystallization method, an SiC source is placed into a crucible, and an SiC seed crystal is placed above the crucible. A tubular guide component is arranged around the SiC seed crystal. The SiC source is heated to generate sublimation gas, which rises along the inner wall of the guide component, leading to the growth of an SiC single crystal on the SiC seed crystal.

SiC single-crystal substrates used for semiconductor devices and the like are produced by epitaxial growth of SiC single crystals on SiC bulk single-crystal substrates. Known methods for epitaxial growth of SiC single crystals include liquid-phase epitaxy (LPE), vapor-phase epitaxy (VPE), and chemical vapor deposition (CVD). Typically, CVD is used as a method for epitaxial growth of SiC single crystals. In the CVD-based method for epitaxial growth, an SiC substrate is placed on a susceptor in an apparatus, and source gases are supplied at a high temperature of 1,500° C. or more to grow an SiC single crystal.

To obtain higher-quality crystals using such a production method for SiC single crystals, PTL 1 discloses a crystal production method using a crucible in which the inner surface of a graphite substrate is coated with tantalum carbide. PTL 2 discloses a crystal production method using a guide component having an inner wall coated with tantalum carbide.

### CITATION LIST

### Patent Literature

PTL 1: JP 2019-99453 A
PTL 2: JP 2019-108611 A

### SUMMARY OF INVENTION

### Technical Problem

It is known that using metal carbide-coated carbon materials as crucibles and guide components to grow SiC single crystals improves crystal growth yield compared to using uncoated carbon materials. Yet even in using metal carbide-coated carbon materials, further improvement in yield is still desired. Major causes of yield loss include point defects, extended defects (dislocations, stacking faults), crystal polymorphs (polytypes), and the like. Among them, the present invention focused on the prevention of crystal polymorphism to improve the yield of semiconductor single crystals.

Therefore, an object of the present invention is to prevent crystal polymorphism in semiconductor single crystals and to improve the yield of semiconductor single crystals by using metal carbide-coated carbon materials.

### Solution to Problem

The present inventors conducted intensive and extensive investigations to achieve this object, and found that controlling the chlorine concentration in the metal carbide coating film of the metal carbide-coated carbon material in the range of 25,000 ppm·μm or less can prevent crystal polymorphism in semiconductor single crystals and improve the yield of semiconductor single crystals. On the basis of this finding, the present inventors have completed the present invention. The scope of the present invention is as follows.
[1] A metal carbide-coated carbon material including a carbon substrate containing carbon as a main component and a metal carbide coating film covering at least part of the carbon substrate, in which the metal carbide constituting the metal carbide coating film is at least one metal carbide selected from the group consisting of tantalum carbide, niobium carbide, zirconium carbide, hafnium carbide, and tungsten carbide, and in which the metal carbide coating film has a chlorine concentration of 25,000 ppm·μm or less.
[2] The metal carbide-coated carbon material according to the above [1], in which the metal carbide coating film has a film thickness of 10 μm or more and 100 μm or less.
[3] The metal carbide-coated carbon material according to the above [1] or [2], in which the surface of the metal carbide coating film has an arithmetic average roughness Ra of 0.1 μm or more and 9.5 μm or less.
[4] The metal carbide-coated carbon material according to any one of the above [1] to [3], in which the surface of the carbon substrate has an arithmetic average roughness Ra of 0.1 μm or more and 10.0 μm or less.
[5] The metal carbide-coated carbon material according to any one of the above [1] to [4], in which the carbon substrate has a linear thermal expansion coefficient of 3.5×10⁻⁶/° C. or more and 8.2×10⁻⁶/° C. or less.
[6] The metal carbide-coated carbon material according to any one of the above [1] to [5], in which the metal carbide constituting at least the surface of the metal carbide coating film is tantalum carbide.
[7] The metal carbide-coated carbon material according to any one of the above [1] to [6], in which the metal carbide constituting the metal carbide coating film is tantalum carbide.

### Advantageous Effects of Invention

The present invention can prevent crystal polymorphism during crystal growth and epitaxial growth of semiconductor single crystals and improve the yield of semiconductor single crystals.

### BRIEF DESCRIPTION OF DRAWINGS

FIG. 1 is a schematic view of a hot-wall low-pressure CVD apparatus according to an embodiment of the present invention.

FIG. 2 is a schematic view of a low-pressure heating furnace for semiconductor single-crystal growth according to an embodiment of the present invention.

FIG. 3 is a schematic view of an apparatus for epitaxial growth of semiconductor single crystals according to an embodiment of the present invention.

FIG. 4 shows the results of GDMS analysis of the tantalum carbide-coated carbon material of Example 1.

FIG. 5 shows the results of cross-sectional SEM observation of the tantalum carbide-coated carbon material of Example 1.

FIG. 6 shows the results of surface SEM observation of the tantalum carbide-coated carbon material of Example 1.

FIG. 7 is a diagram illustrating a method for measuring the adhesion strength of the tantalum carbide coating film.

### DESCRIPTION OF EMBODIMENTS

The metal carbide-coated carbon material according to the present invention will be described using a tantalum carbide-coated carbon material as an example.

### Tantalum Carbide-Coated Carbon Material

The tantalum carbide-coated carbon material according to one embodiment of the present invention includes a carbon substrate containing carbon as a main component and a tantalum carbide coating film covering at least part of the carbon substrate, and the tantalum carbide coating film has a chlorine concentration of 25,000 ppm·μm or less.

### Carbon Substrate

The carbon substrate in the tantalum carbide-coated carbon material according to one embodiment of the present invention is a substrate containing carbon as a main component. The carbon substrate may further contain chlorine. Examples of the material of the carbon substrate include isotropic graphite, extruded graphite, pyrolytic graphite, and carbon fiber reinforced carbon matrix composites (C/C composites). The shape and properties of the carbon substrate are not particularly limited, and the carbon substrate used can be processed into any shape according to the application and the like.

### Arithmetic Surface Roughness Ra

The arithmetic average roughness Ra of the surface of the carbon substrate affects semiconductor single-crystal growth and epitaxial growth. A larger value of the arithmetic average roughness Ra of the surface of the carbon substrate tends to indicate a greater peeling strength of the tantalum carbide coating film from the carbon substrate. For this reason, the arithmetic average roughness Ra of the surface of the carbon substrate is preferably 0.1 μm or more. However, when the arithmetic average roughness Ra of the surface of the carbon substrate is excessively large, the specific surface area of the carbon substrate is increased, and the tantalum carbide coating film is prone to cracking and peeling. As a result, when such a tantalum carbide-coated carbon material is used as the components used for semiconductor single-crystal growth or epitaxial growth, the product life of the components may be shortened. Therefore, in view of the product life of the tantalum carbide-coated carbon material, the arithmetic average roughness Ra of the surface of the carbon substrate is preferably 10.0 μm or less.

In consideration of the incidence of cracking and peeling of the tantalum carbide coating film, the arithmetic average roughness Ra of the surface of the carbon substrate is preferably 0.1 μm or more and 10.0 μm or less, and more preferably 2.0 μm or more and 6.0 μm or less. When the arithmetic average roughness Ra of the surface of the carbon substrate is within the above range, the peeling strength of the tantalum carbide coating film from the carbon substrate can be adjusted to 10 MPa or more. Thus, when such a tantalum carbide-coated carbon material is used as the components for semiconductor single-crystal growth and epitaxial growth, a longer product life of the components can be achieved. The arithmetic average roughness Ra of the surface of the carbon substrate is a value as measured according to JIS B 0633:2001 (ISO 4288:1996).

### Linear Thermal Expansion Coefficient

The linear thermal expansion coefficient of the carbon substrate is preferably 3.5×10⁻⁶/° C. or more and 8.2×10⁻⁶/° C. or less. When the linear thermal expansion coefficient of the carbon substrate is 3.5×10⁻⁶/° C. or more and 8.2×10⁻⁶/° C. or less, microcracking in the tantalum carbide coating film can be further mitigated. In this view, the linear thermal expansion coefficient of the carbon substrate is more preferably 5.0×10⁻⁶ to 7.5×10⁻⁶/° C. The linear thermal expansion coefficient of the tantalum carbide coating film is about 6.3×10⁻⁶/° C. The linear thermal expansion coefficient of the carbon substrate can be measured in accordance with JIS R 1618.

### Tantalum Carbide Coating Film

The tantalum carbide coating film contains tantalum carbide as a main component and has a chlorine concentration of 25,000 ppm·μm or less. The tantalum carbide coating film may cover part of the carbon substrate or the whole carbon substrate. The chlorine concentration herein is on a mass basis.

### Chlorine Concentration

The tantalum carbide coating film in the tantalum carbide-coated carbon material according to one embodiment of the present invention has a chlorine concentration of 25,000 ppm·μm or less. When the chlorine concentration in the tantalum carbide coating film is more than 25,000 ppm·μm, crystal polymorphism in semiconductor single crystals during crystal growth and epitaxial growth of semiconductor single crystals results in a lower yield of semiconductor single crystals. In this view, the chlorine concentration in the tantalum carbide coating film is preferably 10,000 ppm·μm or less, more preferably 5,000 ppm·μm or less, still more preferably 4,000 ppm·μm or less, still more preferably 3,000 ppm·μm or less, still more preferably 1,000 ppm·μm or less, still more preferably 300 ppm·μm or less, still more preferably 200 ppm·μm or less, still more preferably 150 ppm·μm or less, still more preferably 100 ppm·μm or less, still more preferably 50 ppm·μm or less, and particularly preferably 30 ppm·μm or less. The lower limit of the range of the chlorine concentration in the tantalum carbide coating film is not particularly specified and is usually 0.1 ppm·μm or more, or 1 ppm·μm. The chlorine concentration in the tantalum carbide coating film can be measured by the method described in the examples below.

### Explanation for the Mechanism Whereby the Decrease in the Chlorine Concentration in the Tantalum Carbide Coating Film Reduces the Incidence of Crystal Polymorphism

Next, the mechanism whereby the decrease in the chlorine concentration in the tantalum carbide coating film reduces the incidence of crystal polymorphism will be explained, but the explanation mentioned below is not intended to limit the present invention in any way.

Semiconductor single-crystal growth or epitaxial growth is carried out in a high-temperature environment. The tantalum carbide-coated carbon material used as the components for this process is also exposed to a high-temperature environment. Such heat exposure causes the chlorine component in the tantalum carbide coating film to be singly removed from the tantalum carbide coating film or to react with impurity atoms in the tantalum carbide coating film and the carbon substrate, thereby forming halides, which are then removed from the carbon tantalum coating film. In a single-crystal growth environment at high supersaturation of source gases, such a chlorine component or halides are deposited or adsorbed on the facet of the semiconductor single crystal being grown. When the points where the chlorine component or the halides have been deposited or adsorbed serve as starting points for the formation of crystal nuclei, the orientation of each crystal nucleus is randomly determined. This can result in an increased probability of the formation of crystal polymorphs having crystal planes different from that of a crystal grown from the step.

### Method for Measuring the Chlorine Concentration in the Tantalum Carbide Coating Film

The chlorine concentration in the tantalum carbide coating film can be measured, for example, by glow discharge mass spectrometry (GDMS) using a glow discharge mass spectrometer manufactured by VG Elemental (trade name “VG9000”) under the following measurement conditions.

### Measurement Conditions

Discharge Gas: Ar (7 N)
Insulator: Ceramic
Secondary Electrode: In Orifice
Cell: Flat Cell Assembly
Nomakization: 1 kV, 1.6 mA
Ion Current: Ta ca. 1.2×E−11 A
Detectors: Faraday cup: 160 msec
Daly-multiplier: 500 msec

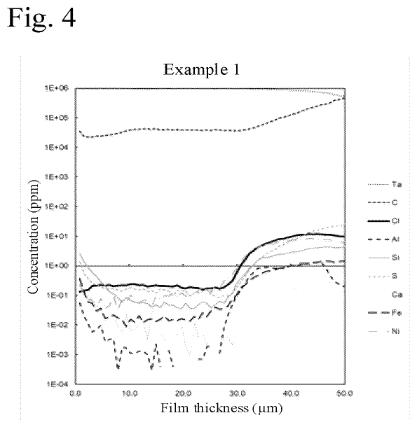

Measurement data are expressed as ion beam ratios (IBRs) corrected by a relative sensitivity factor (RSF). The RSF used here is a built-in standard value in the software. The RSF varies with measurement conditions and the shape of a discharge cell, and the values corrected by the built-in RSF in the software (RSF corrected values) are considered to be more approximate to the mass concentrations than IBRs. The results of Example 1 described below are shown in FIG. 4 as an example of the measurement data. The vertical axis represents the concentration (weight ppm), and the horizontal axis represents the depth (μm). The depth is a converted value based on the value of the crater depth measured after the analysis on the assumption that sputtering rate is constant during the analysis. The depth resolution is deemed to have an error of about 10 percent or slightly more because the crater bottom after analysis has an unevenness of about a few micrometers.

For the definition of the term “in the metal carbide coating film”, the point where the change in carbon concentration is observed in the GDMS analysis is set as the location of the interface between the tantalum carbide coating film and the carbon substrate, on the condition that there is a correlation with the measured value of the film thickness obtained by cross-sectional observation using a scanning electron microscope (SEM) or other instruments. For example, as for Example 1 described below, the results of cross-sectional SEM observation show that the film thickness is 30 μm, and for example, the measurement data shown in FIG. 4 indicate an increase in carbon concentration at around 30 μm. Accordingly, for example, in the measurement data shown in FIG. 4, the range from a depth of 0 μm to a depth of 30 μm, where the carbon concentration sharply increases, is regarded as “in the metal carbide coating film”.

The chlorine concentration is a value calculated by integration of the chlorine concentration over the range represented by “in the metal carbide coating film”. For example, in the measurement data shown in FIG. 4, the integral value of the chlorine concentration from a depth of 0 μm to a depth of 30 μm is regarded as the “chlorine concentration”. The value of the chlorine concentration in the measurement data shown in FIG. 4 is 27.5 ppm·μm.

### Other Atoms

The tantalum carbide coating film, which contains tantalum carbide as a main component and has a chlorine concentration of 25,000 ppm·μm or less, may contain a trace amount of an atom other than carbon, tantalum, and chlorine to the extent that such an atom does not interfere with the effects of the present invention. For example, the tantalum carbide coating film may contain an impurity element and/or a doping element other than carbon, tantalum, and chlorine at a concentration of 10,000 ppm·μm or less.

### Method for Producing the Tantalum Carbide-Coated Carbon Material

The tantalum carbide-coated carbon material according to one embodiment of the present invention can be produced by forming a tantalum carbide layer on the surface of a carbon substrate. For example, the tantalum carbide coating film can be formed on the surface of the carbon substrate by chemical vapor deposition (CVD), sintering, carbonization, or the like. Among these techniques, CVD is a preferable technique for forming the tantalum carbide coating film because CVD enables the formation of a uniform and dense tantalum carbide coating film.

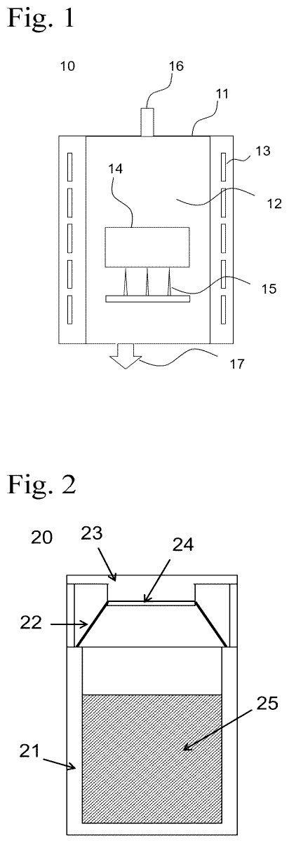

Furthermore, CVD includes thermal CVD, photo CVD, and plasma-enhanced CVD. The tantalum carbide layer can be formed by, for example, thermal CVD. Thermal CVD has some advantages such as using an apparatus with a relatively simple configuration and not causing plasma-induced damage in carbon substrates. For the formation of the tantalum carbide coating film by thermal CVD, for example, a hot-wall low-pressure CVD apparatus 10 as shown in FIG. 1 can be used. In the hot-wall low-pressure CVD apparatus 10, a carbon substrate 14 is supported by a support means 15 in a reaction chamber 12 provided with a heater 13, a source supply unit 16, an exhaust unit 17, and others.

The method for producing the tantalum carbide-coated carbon material according to one embodiment of the present invention will be described with reference to FIG. 1.

First, a carbon substrate 14 is placed in a reaction chamber 12 of a hot-wall low-pressure CVD apparatus 10. The carbon substrate 14 is supported by a support means 15 having three support parts each having a sharply pointed tip.

Next, the reaction chamber 12 is heated. For example, the reaction chamber 12 is heated under the conditions of an atmospheric pressure of 10 to 1,000 Pa and a temperature of 800 to 2,200° C.

Then, a tantalum carbide coating film is formed on the surface of the carbon substrate 14. As source gases, a carbon atom-containing compound gas such as methane (CH₄), hydrogen (H₂) gas, and a tantalum halide gas such as tantalum pentachloride (TaCl₅) are supplied into the reaction chamber 12 from a source supply unit 16. The tantalum halide gas can be generated, for example, by heating and vaporizing a tantalum halide, by reacting a tantalum metal with a halogen gas, or by other methods. Then, the source gases supplied from the source supply unit 16 are subjected to a thermal CVD reaction at a high temperature of 800 to 2,200° C. under a low pressure of 1 to 1,000 Pa to form a tantalum carbide coating film on the carbon substrate 14.

### Method for Controlling the Chlorine Concentration in the Tantalum Carbide Coating Film

In the supply of source gases, hydrogen (H₂) gas is supplied, which facilitates the elimination reaction of chlorine from the tantalum halide gas, thereby enabling the control of the chlorine concentration in the tantalum carbide layer in the range of 25,000 ppm·μm or less.

The mole ratio of the hydrogen atom in the hydrogen gas to the tantalum atom in the tantalum halide gas in the source gases preferably satisfies the following equation.

$$Tantalum atom ( Ta ) : Hydeogen atom ( H ) = 1 : x ( 4 \leq x < 16 )$$

When the value of x is 16 or more, the removal of chlorine from the tantalum halide gas is facilitated, but a tantalum carbide coating film excessively containing Ta is formed, such as a Ta₂C or Ta metal film, in which the mole ratio of Ta:C is not 1:1. Here, the mole ratio of the hydrogen atom in the hydrogen gas to the tantalum atom in the tantalum halide gas in the source gases can be calculated from the volumetric flow rates of the tantalum halide gas and the hydrogen gas in the standard state. For example, when tantalum pentachloride is used as the tantalum halide gas, one mole of the tantalum halide gas contains one mole of a tantalum atom. On the other hand, one mole of the hydrogen gas contains two moles of a hydrogen atom.

The above-described tantalum carbide-coated carbon material according to one embodiment of the present invention is one example of the metal carbide-coated carbon material according to the present invention, and the metal carbide-coated carbon material according to the present invention is not limited to the tantalum carbide-coated carbon material according to one embodiment of the present invention. In the metal carbide-coated carbon material according to the present invention, the metal carbide constituting the metal carbide coating film covering the carbon substrate is not limited to tantalum carbide. For example, niobium carbide, zirconium carbide, hafnium carbide, tungsten carbide, and other carbides can be used as the metal carbide constituting the metal carbide coating film covering the carbon substrate. In addition, a combination of two or more metal carbides selected from the group consisting of tantalum carbide, niobium carbide, zirconium carbide, hafnium carbide, and tungsten carbide may be used as the metal carbide constituting the metal carbide coating film covering the carbon substrate. Among tantalum carbide, niobium carbide, zirconium carbide, hafnium carbide, and tungsten carbide, tantalum carbide is preferable because it has the highest melting point and also has superior chemical stability, strength, and corrosion resistance.

When tantalum carbide is used for the metal carbide coating film, it is not necessary that the whole metal carbide coating film be made of tantalum carbide and it is sufficient that at least the surface of the metal carbide coating film be made of tantalum carbide.

### EXAMPLES

Hereinafter, examples are provided to describe the present invention in more detail, but the present invention is not limited thereto.

Metal carbide-coated carbon materials of Examples 1 to 21 and Comparative Example 1 were produced as follows.

### Example 1

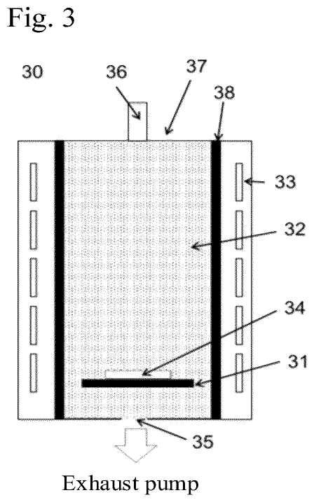

First, as shown in FIGS. 2 and 3, isotropic graphite was processed into a bottomed hollow cylindrical shape (crucible 21), a truncated conical tubular shape (guide component 22), a disk shape (susceptor 31), and a hollow cylindrical shape (inner wall component 38), each of which was used as a carbon substrate (see sign 14 in FIG. 1). The arithmetic average roughness Ra of the surface of the carbon substrate 14 was 6.0 μm, and the linear thermal expansion coefficient of the carbon substrate 14 was 7.0×10⁻⁶/° C. Regarding the linear thermal expansion coefficient of the carbon substrate, a thermomechanical analyzer (TMA7300) manufactured by Yamato Scientific Co., Ltd. was used, and the value of the thermal expansion coefficient in the temperature ranging from 200° C. to 1,200° C. was used.

Next, the carbon substrate 14 was placed in a reaction chamber 12 of a hot-wall low-pressure CVD apparatus 10 shown in FIG. 1. The carbon substrate 14 was supported by a support means 15 having three support parts each having a sharply pointed tip. At this time, the tip of each support part was in contact with the outer surface of the carbon substrate 14 in a truncated conical tubular shape, the outer surface of the carbon substrate 14 in a bottomed hollow cylindrical shape, the bottom surface of the carbon substrate 14 in a disk shape, and the outer surface of the carbon substrate 14 in a hollow cylindrical shape.

Then, 0.25 SLM of methane (CH₄) gas, 1.0 SLM of argon (Ar) gas as a carrier gas, 0.125 SLM of hydrogen (H₂) gas, and 0.25 SLM of tantalum pentachloride (TaCl₅), which was heated at a temperature of 220° C. and vaporized, were supplied into the reaction chamber 12 from a source supply unit 16, and the source gases were reacted in the reaction chamber 12 under the conditions of an atmospheric pressure of 100 Pa and a temperature of 1,250° C. to form a tantalum carbide coating film on the entire surface of the carbon substrate 14.

The carbon substrate 14 covered with the tantalum carbide coating film was taken out from the reaction chamber 12. Thus, a crucible 21 (see FIG. 2), a guide component 22 (see FIG. 2), a susceptor 31 (see FIG. 3), and an inner wall component 38 (see FIG. 3) each made of the tantalum carbide-coated carbon material were completed.

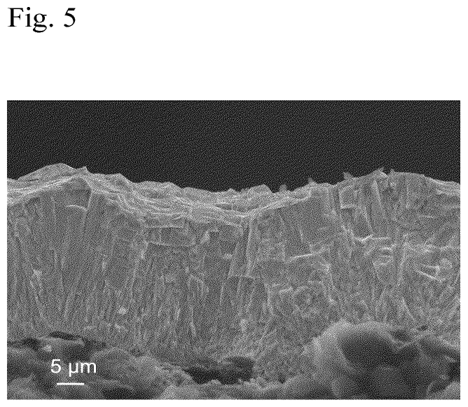

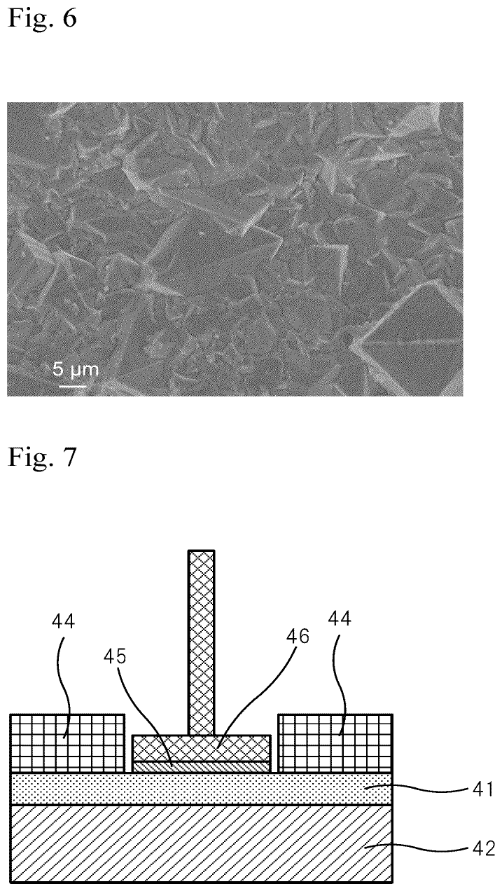

The film thickness of the tantalum carbide coating film was calculated to be 30 μm on the basis of cross-sectional observation using a scanning electron microscope (SEM). SEM cross-sectional images of the tantalum carbide coating film in the tantalum carbide-coated carbon material of Example 1 are shown in FIGS. 5 and 6.

Regarding the surface of the tantalum carbide coating film, the arithmetic average roughness Ra of the surface of the tantalum carbide coating film was measured using a surface roughness tester (manufactured by Mitutoyo Corporation, trade name “Surftest SJ-210”). The results show that the arithmetic average roughness Ra of the surface of the tantalum carbide coating film was 5.5 μm.

In addition, the chlorine concentration in the tantalum carbide coating film was measured by glow discharge mass spectrometry (GDMS) as described above in the description. The measurement data are shown in FIG. 4. The results show that the chlorine concentration in the tantalum carbide coating film was 27.5 ppm·μm.

The adhesion strength of the tantalum carbide coating film was measured and found to be 19.6 MPa. The adhesion strength of the tantalum carbide coating film was measured by the following method.

The measurement of the adhesion strength of the tantalum carbide coating film was performed, for example, using a thin film adhesion strength tester (manufactured by Quad Group Inc., trade name “Romulus”). As shown in FIG. 7, a tantalum carbide coating film 41 and a stud pin 46 were bonded together with an adhesive 45, the tantalum carbide coating film was firmly held with a holding jig 44, and the stud pin 46 was pulled. The stress at which the tantalum carbide coating film 41 was detached was measured. Five measurements were taken, and the average value calculated from the five measurements was used as the adhesion strength of the tantalum carbide coating film.

The fabricated crucible 21 and guide component 22 were mounted in a low-pressure heating furnace 20 as shown in FIG. 2, and an SiC single crystal was grown by the sublimation-recrystallization method. An SiC source 25 was placed into the crucible 21, and an SiC seed crystal 24 with a diameter of 2 inches was placed above the crucible. With argon gas being supplied at a flow rate of 10 to 30 SLM into the low-pressure heating furnace 20, the SiC source 25 was sublimated under the conditions of an atmospheric pressure of 500 to 1,000 Pa and a temperature of 2,000 to 2,500° C., and an SiC single crystal with a thickness of 5 mm was grown on the SiC seed crystal 24.

The SiC single-crystal production was repeated multiple times to determine the number of cycles the crucible 21 and the guide component 22 could be used. As the result, after 24 cycles of use, the peeling of the tantalum carbide coating film was observed in the crucible 21, resulting in the need for the replacement of the components with new ones.

The fabricated susceptor 31 and inner wall component 38 were mounted in a CVD apparatus 30 as shown in FIG. 3, and an SiC single crystal was epitaxially grown by CVD. An SiC single-crystal substrate 34, which was prepared by processing a bulk single crystal into a board shape, was placed on the susceptor 31. While monosilane (SiH₄) gas and propane (C₃H₈) gas were supplied at 30 sccm and 70 sccm, respectively, into the CVD apparatus at an atmospheric pressure of 45 Torr and a temperature of 1,550° C., an SiC single crystal was epitaxially grown on the SiC single-crystal substrate.

The SiC single-crystal production was repeated multiple times to determine the number of cycles the susceptor 31 and the inner wall component 38 could be used. As the result, after 96 cycles of use, the peeling of the tantalum carbide coating film was observed, resulting in the need for the replacement of the components with new ones.

In addition, the incidence of crystal polymorphism in the obtained single crystals was examined. The incidence of crystal polymorphism in the SiC single crystals produced by the sublimation-recrystallization method and the incidence of crystal polymorphism in the SiC single crystals produced by epitaxial growth were both 0%. The incidence of crystal polymorphism was measured as follows.

The grown SiC single crystals were exposed to ultraviolet (UV) light, and their Any slight crystal disorder observed was regarded as crystal appearance was examined. polymorphism.

### Example 2

A crucible 12, a guide component 19, a susceptor 31, and an inner wall component 38 were fabricated and evaluated in the same manner as in Example 1, except that the flow rate of hydrogen (H₂) gas was changed from 0.125 SLM to 0.2 SLM. The results are shown in Table 2.

### Example 3

A crucible 12, a guide component 19, a susceptor 31, and an inner wall component 38 were fabricated and evaluated in the same manner as in Example 1, except that the flow rate of hydrogen (H₂) gas was changed from 0.125 SLM to 0.15 SLM and the flow rate of tantalum pentachloride (TaCl₅) was changed from 0.25 SLM to 0.3 SLM. The results are shown in Table 2.

### Example 4

A crucible 12, a guide component 19, a susceptor 31, and an inner wall component 38 were fabricated and evaluated in the same manner as in Example 1, except that the flow rate of hydrogen (H₂) gas was changed from 0.125 SLM to 0.2 SLM and the flow rate of tantalum pentachloride (TaCl₅) was changed from 0.25 SLM to 0.4 SLM. The results are shown in Table 2.

### Example 5

A crucible 12, a guide component 19, a susceptor 31, and an inner wall component 38 were fabricated and evaluated in the same manner as in Example 1, except that the flow rate of hydrogen (H₂) gas was changed from 0.125 SLM to 0.25 SLM and the flow rate of tantalum pentachloride (TaCl₅) was changed from 0.25 SLM to 0.5 SLM. The results are shown in Table 2.

### Example 6

A crucible 12, a guide component 19, a susceptor 31, and an inner wall component 38 were fabricated and evaluated in the same manner as in Example 1, except that the flow rate of hydrogen (H₂) gas was changed from 0.125 SLM to 0.15 SLM, the flow rate of tantalum pentachloride (TaCl₅) was changed from 0.25 SLM to 0.3 SLM, and the film thickness was changed from 30 μm to 10 μm by shortening the film formation time. The results are shown in Table 2.

### Example 7

A crucible 12, a guide component 19, a susceptor 31, and an inner wall component 38 were fabricated and evaluated in the same manner as in Example 1, except that the flow rate of hydrogen (H₂) gas was changed from 0.125 SLM to 0.15 SLM and the film thickness was changed from 30 μm to 50 μm by extending the film formation time. The results are shown in Table 2.

### Example 8

A crucible 12, a guide component 19, a susceptor 31, and an inner wall component 38 were fabricated and evaluated in the same manner as in Example 1, except that the arithmetic average roughness Ra of the surface of each carbon substrate 14 was changed from 6.0 μm to 0.1 μm. The results are shown in Table 2.

### Example 9

A crucible 12, a guide component 19, a susceptor 31, and an inner wall component 38 were fabricated and evaluated in the same manner as in Example 1, except that the arithmetic average roughness Ra of the surface of each carbon substrate 14 was changed from 6.0 μm to 10 μm. The results are shown in Table 2.

### Example 10

A crucible 12, a guide component 19, a susceptor 31, and an inner wall component 38 were fabricated and evaluated in the same manner as in Example 1, except that the thermal expansion coefficient of each carbon substrate 14 was changed from 7.0×10⁻⁶/° C. to 3.5×10⁻⁶/° C. The results are shown in Table 2.

### Example 11

A crucible 12, a guide component 19, a susceptor 31, and an inner wall component 38 were fabricated and evaluated in the same manner as in Example 1, except that the thermal expansion coefficient of each carbon substrate 14 was changed from 7.0×10⁻⁶/° C. to 8.2×10⁻⁶/° C. The results are shown in Table 2.

### Example 12

A crucible 12, a guide component 19, a susceptor 31, and an inner wall component 38 were fabricated and evaluated in the same manner as in Example 1, except that the metal chloride gas was changed from tantalum pentachloride (TaCl₅) to niobium pentachloride (NbCl₅) without changing the flow rate (0.25 SLM) of the metal chloride gas. The results are shown in Table 2.

### Example 13

A crucible 12, a guide component 19, a susceptor 31, and an inner wall component 38 were fabricated and evaluated in the same manner as in Example 1, except that the metal chloride gas was changed from tantalum pentachloride (TaCl₅) to hafnium tetrachloride (HfCl₄) without changing the flow rate (0.25 SLM) of the metal chloride gas. The results are shown in Table 2.

### Example 14

A crucible 12, a guide component 19, a susceptor 31, and an inner wall component 38 were fabricated and evaluated in the same manner as in Example 1, except that the metal chloride gas was changed from tantalum pentachloride (TaCl₅) to zirconium tetrachloride (ZrCl₄) without changing the flow rate (0.25 SLM) of the metal chloride gas. The results are shown in Table 2.

### Example 15

A crucible 12, a guide component 19, a susceptor 31, and an inner wall component 38 were fabricated and evaluated in the same manner as in Example 1, except that the metal chloride gas was changed from tantalum pentachloride (TaCl₅) to tungsten pentachloride (WCl₅) without changing the flow rate (0.25 SLM) of the metal chloride gas. The results are shown in Table 2.

### Example 16

A crucible 12, a guide component 19, a susceptor 31, and an inner wall component 38 were fabricated and evaluated in the same manner as in Example 1, except that the metal chloride gas was changed from tantalum pentachloride (TaCl₅) to a mixed gas of tantalum pentachloride (TaCl₅) and niobium pentachloride (NbCl₅) (TaCl₅:NbCl₅=100:1) without changing the flow rate (0.25 SLM) of the metal chloride gas. The results are shown in Table 2.

### Example 17

A crucible 12, a guide component 19, a susceptor 31, and an inner wall component 38 were fabricated and evaluated in the same manner as in Example 1, except that the metal chloride gas was changed from tantalum pentachloride (TaCl₅) to a mixed gas of tantalum pentachloride (TaCl₅) and tungsten pentachloride (WCl₅) (TaCl₅:WCl₅=100:1) without changing the flow rate (0.25 SLM) of the metal chloride gas. The results are shown in Table 2.

### Example 18

A crucible 12, a guide component 19, a susceptor 31, and an inner wall component 38 were fabricated and evaluated in the same manner as in Example 1, except that the film thickness was changed from 30 μm to 2 μm by shortening the film formation time. The results are shown in Table 2.

### Example 19

A crucible 12, a guide component 19, a susceptor 31, and an inner wall component 38 were fabricated and evaluated in the same manner as in Example 1, except that the arithmetic average roughness Ra of the surface of each carbon substrate 14 was changed from 6.0 μm to 32 μm. The results are shown in Table 2.

### Example 20

A crucible 12, a guide component 19, a susceptor 31, and an inner wall component 38 were fabricated and evaluated in the same manner as in Example 1, except that the arithmetic average roughness Ra of the surface of each carbon substrate 14 was changed from 6.0 μm to 0.05 μm. The results are shown in Table 2.

### Example 21

A crucible 12, a guide component 19, a susceptor 31, and an inner wall component 38 were fabricated and evaluated in the same manner as in Example 1, except that the thermal expansion coefficient of each carbon substrate 14 was changed from 7.0×10⁻⁶/° C. to 1.9×10⁻⁶/° C. The results are shown in Table 1.

### Comparative Example 1

A crucible 12, a guide component 19, a susceptor 31, and an inner wall component 38 were fabricated and evaluated in the same manner as in Example 1, except that the flow rate of hydrogen (H₂) gas was changed from 0.125 SLM to 0 SLM and the flow rate of tantalum pentachloride (TaCl₅) was changed from 0.25 SLM to 0.5 SLM. The results are shown in Table 2.

The production conditions for Examples 1 to 21 and Comparative Example 1 are shown in Table 1.

TABLE 1

| | | Flow rate of | | | |
|---|---|---|---|---|---|
| | Metal halide | metal halide gas | Flow rate of | Flow rate of | Flow rate of |
| | gas species | (SLM) | C gas (SLM) | H₂ gas (SLM) | Ar gas (SLM) |
| Example 1 | TaCl₅ | 0.25 | 0.25 | 0.125 | 1.00 |
| Example 2 | TaCl₅ | 0.25 | 0.25 | 0.2 | 1.00 |
| Example 3 | TaCl₅ | 0.3 | 0.25 | 0.15 | 1.00 |
| Example 4 | TaCl₅ | 0.4 | 0.25 | 0.2 | 1.00 |
| Example 5 | TaCl₅ | 0.5 | 0.25 | 0.25 | 1.00 |
| Example 6 | TaCl₅ | 0.3 | 0.25 | 0.15 | 1.00 |
| Example 7 | TaCl₅ | 0.25 | 0.25 | 0.15 | 1.00 |
| Example 8 | TaCl₅ | 0.25 | 0.25 | 0.125 | 1.00 |
| Example 9 | TaCl₅ | 0.25 | 0.25 | 0.125 | 1.00 |
| Example 10 | TaCl₅ | 0.25 | 0.25 | 0.125 | 1.00 |
| Example 11 | TaCl₅ | 0.25 | 0.25 | 0.125 | 1.00 |
| Example 12 | TaCl₅ | 0.25 | 0.25 | 0.125 | 1.00 |
| Example 13 | HfCl₄ | 0.25 | 0.25 | 0.125 | 1.00 |
| Example 14 | ZrCl₄ | 0.25 | 0.25 | 0.125 | 1.00 |
| Example 15 | WCl₅ | 0.25 | 0.25 | 0.125 | 1.00 |
| Example 16 | TaCl₅ + NbCl₅ | 0.25 | 0.25 | 0.125 | 1.00 |
| Example 17 | TaCl₅ + WCl₅ | 0.25 | 0.25 | 0.125 | 1.00 |
| Example 18 | TaCl₅ | 0.25 | 0.25 | 0.125 | 1.00 |
| Example 19 | TaCl₅ | 0.25 | 0.25 | 0.125 | 1.00 |
| Example 20 | TaCl₅ | 0.25 | 0.25 | 0.125 | 1.00 |
| Example 21 | TaCl₅ | 0.25 | 0.25 | 0.125 | 1.00 |
| Comparative | TaCl₅ | 0.5 | 0.25 | 0 | 1.00 |
| Example 1 | | | | | |

| | Formation temperature for | Formation time for |
|---|---|---|
| | tantalum carbide layer (° C.) | tantalum carbide layer (H) |
| Example 1 | 1250 | 10 |
| Example 2 | 1250 | 10 |
| Example 3 | 1250 | 10 |
| Example 4 | 1250 | 10 |
| Example 5 | 1250 | 10 |
| Example 6 | 1250 | 3 |
| Example 7 | 1250 | 17 |
| Example 8 | 1250 | 10 |
| Example 9 | 1250 | 10 |
| Example 10 | 1250 | 10 |
| Example 11 | 1250 | 10 |
| Example 12 | 1250 | 10 |
| Example 13 | 1250 | 10 |
| Example 14 | 1250 | 10 |
| Example 15 | 1250 | 10 |
| Example 16 | 1250 | 10 |
| Example 17 | 1250 | 10 |
| Example 18 | 1250 | 0.5 |
| Example 19 | 1250 | 10 |
| Example 20 | 1250 | 10 |
| Example 21 | 1250 | 10 |
| Comparative | 1250 | 10 |
| Example 1 | | |

The evaluation results of Examples 1 to 21 and Comparative Example 1 are shown in Table 2.

TABLE 2

| | Cl concentration | Film thickness | Surface roughness Ra | | Thermal expansion |
|---|---|---|---|---|---|
| | in metal carbide | of metal carbide | (μm) | | coefficient of |
| | film | film | | Metal | substrate |
| | (ppm · μm) | (μm) | Substrate | carbide | (×10⁻⁶° C.) |
| Example 1 | 27.5 | 30 | 6 | 5.5 | 7.0 |
| Example 2 | 1 | 30 | 6 | 5.5 | 7.0 |
| Example 3 | 100 | 30 | 6 | 5.5 | 7.0 |
| Example 4 | 2000 | 30 | 6 | 5.5 | 7.0 |
| Example 5 | 25000 | 30 | 6 | 5.5 | 7.0 |
| Example 6 | 22.5 | 10 | 6 | 5.5 | 7.0 |
| Example 7 | 102.2 | 50 | 6 | 5.5 | 7.0 |
| Example 8 | 27.5 | 30 | 0.1 | 1.5 | 7.0 |
| Example 9 | 27.5 | 30 | 10 | 9.5 | 7.0 |
| Example 10 | 27.5 | 30 | 6 | 5.5 | 3.5 |
| Example 11 | 27.5 | 30 | 6 | 5.5 | 8.2 |
| Example 12 | 3300 | 30 | 6 | 5.5 | 7.0 |
| Example 13 | 4500 | 30 | 6 | 5.5 | 7.0 |
| Example 14 | 3500 | 30 | 6 | 5.5 | 7.0 |
| Example 15 | 4400 | 30 | 6 | 5.5 | 7.0 |
| Example 16 | 202 | 30 | 6 | 5.5 | 7.0 |
| Example 17 | 198 | 30 | 6 | 5.5 | 7.0 |
| Example 18 | 2.5 | 2 | 6 | 5.5 | 7.0 |
| Example 19 | 27.5 | 30 | 32 | 31.5 | 7.0 |
| Example 20 | 27.5 | 30 | 0.05 | 0.01 | 7.0 |
| Example 21 | 27.5 | 30 | 6 | 5.5 | 1.9 |
| Comparative | 100000 | 30 | 6 | 5.5 | 7.0 |
| Example 1 | | | | | |

| | | Number of cycles of use | | Incidence of crystal | |
|---|---|---|---|---|---|
| | Adhesion | (cycles) | | polymorphism (%) | |
| | strength | Sublimation | Epitaxial | Sublimation | Epitaxial |
| | (MPa) | method | growth | method | growth |
| Example 1 | 19.6 | 24 | 96 | 0 | 0 |
| Example 2 | 18.5 | 20 | 76 | 0 | 0 |
| Example 3 | 24.6 | 23 | 91 | 0 | 0 |
| Example 4 | 30.1 | 22 | 94 | 0 | 0 |
| Example 5 | 35.1 | 24 | 96 | 0 | 0 |
| Example 6 | 15.6 | 10 | 40 | 0 | 0 |
| Example 7 | 27.4 | 22 | 86 | 0 | 0 |
| Example 8 | 11.3 | 8 | 35 | 0 | 0 |
| Example 9 | 40.5 | 12 | 42 | 0 | 0 |
| Example 10 | 14.6 | 6 | 39 | 0 | 0 |
| Example 11 | 26.6 | 22 | 88 | 0 | 0 |
| Example 12 | 21.3 | 24 | 75 | 0 | 0 |
| Example 13 | 22.6 | 20 | 72 | 0 | 0 |
| Example 14 | 27.5 | 18 | 60 | 0 | 0 |
| Example 15 | 25.5 | 15 | 66 | 0 | 0 |
| Example 16 | 25.5 | 15 | 66 | 0 | 0 |
| Example 17 | 24.5 | 14 | 58 | 0 | 0 |
| Example 18 | 22.5 | 3 | 9 | 33 | 11 |
| Example 19 | 18.5 | 1 | 5 | 20 | 20 |
| Example 20 | 2.1 | 1 | 5 | 0 | 0 |
| Example 21 | 24.5 | 1 | 5 | 50 | 20 |
| Comparative | 15.4 | 3 | 10 | 67 | 33 |
| Example 1 | | | | | |

Comparison between the results of Examples 1 to 21 and the results of Comparative Example 1 shows that controlling the chlorine concentration in the metal carbide coating film in the range of 25,000 ppm·μm or less can prevent crystal polymorphism during crystal growth and epitaxial growth of semiconductor single crystals.

Comparison between the results of Examples 1 to 5 and the results of Comparative Example 1 shows that when the chlorine concentration in the tantalum carbide coating film was in the range of 25,000 ppm·μm or less, the product life of the metal carbide-coated carbon material was prolonged, and crystal polymorphism during crystal growth and epitaxial growth of semiconductor single crystals was prevented. Since crystal polymorphism was observed in the tantalum carbide-coated carbon materials of Comparative Example 1, their repeated use was discontinued before the tantalum carbide-coated carbon materials became unusable due to the peeling of the tantalum carbide coating film or other reasons.

Comparison between the results of Examples 1, 6, and 7, and the results of Example 18 shows that when the film thickness of the tantalum carbide coating film was 10 μm or more and 100 μm or less, the product life of the metal carbide-coated carbon material was prolonged, and crystal polymorphism during crystal growth and epitaxial growth of semiconductor single crystals was prevented. When the film thickness of the tantalum carbide coating film was 10 μm or less, crystal polymorphism during crystal growth and epitaxial growth of semiconductor single crystals was observed. Since crystal polymorphism was observed in the tantalum carbide-coated carbon materials of Example 18, their repeated use was discontinued before the tantalum carbide-coated carbon materials became unusable due to the peeling of the tantalum carbide coating film or other reasons. The film thickness of the tantalum carbide coating film exceeding 100 μm is undesirable because of a prolonged film formation time, which increases the film formation cost. Therefore, the film thickness of the tantalum carbide coating film in the range of 10 μm or more and 100 μm or less is preferable.

Comparison between the results of Examples 1, 8, and 9, and the results of Examples 19 and 20 shows that when the arithmetic average roughness Ra of the surface of the metal carbide coating film was 0.1 μm or more and 9.5 μm or less, or when the arithmetic average roughness Ra of the surface of the carbon substrate was 0.1 μm or more and 10.0 μm or less, the product life of the metal carbide-coated carbon material was prolonged, and crystal polymorphism during crystal growth and epitaxial growth of semiconductor single crystals was prevented. When the arithmetic average roughness Ra of the surface of the carbon substrate was more than 10 μm, the product life of the metal carbide-coated carbon material was shortened, and crystal polymorphism during crystal growth and epitaxial growth of semiconductor single crystals was observed. When the arithmetic average roughness Ra of the surface of the carbon substrate was less than 0.1 μm, the product life of the metal carbide-coated carbon material was shortened.

Comparison between the results of Examples 1, 10, and 11, and the results of Example 21 shows that when the thermal expansion coefficient of the carbon substrate was 3.5×10⁻⁶/° C. or more and 8.2×10⁻⁶/° C. or less, the product life of the metal carbide-coated carbon material was prolonged, and crystal polymorphism during crystal growth and epitaxial growth of semiconductor single crystals was prevented. When the thermal expansion coefficient of the carbon substrate was less than 3.5×10⁻⁶/° C., the product life of the metal carbide-coated carbon material was shortened, and crystal polymorphism during crystal growth and epitaxial growth of semiconductor single crystals was observed.

Comparison of the results of Example 1 and Examples 12 to 16 shows that when the metal carbide-coated carbon materials was configured to include a metal carbide coating film that covers at least part of the surface of the substrate containing carbon as a main component, mainly contains one metal carbide or a combination of two or more metal carbides selected from among tantalum carbide, niobium carbide, zirconium carbide, hafnium carbide, and tungsten carbide, and has a chlorine concentration of 25,000 ppm·μm or less, the product life of the metal carbide-coated carbon material was prolonged, and crystal polymorphism during crystal growth and epitaxial growth of semiconductor single crystals was prevented.

### REFERENCE SIGNS LIST

10 Hot-wall low-pressure CVD apparatus
11 Top chamber
12 Reaction chamber
13 Heater
14 Carbon substrate
15 Support means
16 Source supply unit
17 Exhaust unit
20 Low-pressure heating furnace
21 Crucible
22 Guide component
23 Upper lid
24 SiC seed crystal
25 SiC source
30 Epitaxial growth apparatus
31 Susceptor
32 Reaction chamber
33 Heater
34 SiC single-crystal substrate
35 Exhaust unit
36 Source supply unit
37 Top chamber
38 Inner wall component
41 Tantalum carbide coating film
42 Carbon substrate
44 Holding jig
45 Adhesive
46 Stud pin

1. A metal carbide-coated carbon material comprising a carbon substrate containing carbon as a main component and a metal carbide coating film covering at least part of the carbon substrate,
wherein the metal carbide constituting the metal carbide coating film is at least one metal carbide selected from the group consisting of tantalum carbide, niobium carbide, zirconium carbide, hafnium carbide, and tungsten carbide, and
wherein the metal carbide coating film has a chlorine concentration of 25,000 ppm·μm or less.

2. The metal carbide-coated carbon material according to claim 1, wherein the metal carbide coating film has a film thickness of 10 μm or more and 100 μm or less.

3. The metal carbide-coated carbon material according to claim 1, wherein the surface of the metal carbide coating film has an arithmetic average roughness Ra of 0.1 μm or more and 9.5 μm or less.

4. The metal carbide-coated carbon material according to claim 1, wherein the surface of the carbon substrate has an arithmetic average roughness Ra of 0.1 μm or more and 10.0 μm or less.

5. The metal carbide-coated carbon material according to claim 1, wherein the carbon substrate has a linear thermal expansion coefficient of 3.5×10⁻⁶/° C. or more and 8.2× 10⁻⁶/° C. or less.

6. The metal carbide-coated carbon material according to claim 1, wherein the metal carbide constituting at least the surface of the metal carbide coating film is tantalum carbide.

7. The metal carbide-coated carbon material according to claim 1, wherein the metal carbide constituting the metal carbide coating film is tantalum carbide.
